(19) United States
(12) Patent Application Publication
(10) Pub. No.: US 2006/0017084 A1
(43) Pub. Date: Jan. 26, 2006

(54) Integrated semiconductor metal-insulator-semiconductor capacitor

(76) Inventors: Feng Gao, Sunnyvale, CA (US); Changyuan Chen, Sunnyvale, CA (US); Vishal Sarin, Cupertino, CA (US); William John Saiki, Mountain View, CA (US); Hieu Van Tran, San Jose, CA (US); Dana Lee, Santa Clara, CA (US)

Correspondence Address: DLA PIPER RUDNICK GRAY CARY US, LLP, 2000 UNIVERSITY AVENUE, E. PALO ALTO, CA, 94303-2248, US

(21) Appl. No.: 10/897,045

(22) Filed: Jul. 22, 2004

(51) Int. Cl. H01L 29/76

(52) U.S. Cl. 257/296

(57) ABSTRACT

An integrated MIS capacitor has two substantially identical MIS capacitors. A first capacitor comprises a first region of a first conductivity type adjacent to a channel region of the first conductivity type in a semiconductor substrate. The semiconductor substrate has a second conductivity type. A gate electrode is insulated and spaced apart from the channel region of the first capacitor. The second capacitor is substantially identical to the first capacitor and is formed in the same semiconductor substrate. The gate electrode of the first capacitor is electrically connected to the first region of the second capacitor and the gate electrode of the second capacitor is electrically connected to the first region of the first capacitor. In this manner, the capacitors are connected in an anti-parallel configuration. A capacitor which has high capacitance densities, low process complexity, ambipolar operation, low voltage and temperature coefficient, low external parasitic resistance and capacitance and good matching characteristics for use in analog designs that can be integrated with existing semiconductor processes results.

### TECHNICAL FIELD

The present invention relates to an integrated metal-insulator-semiconductor (MIS) capacitor having two MIS capacitors which are connected in an anti-parallel configuration.

### BACKGROUND OF THE INVENTION

Integrated MIS capacitors are well-known in the art. Referring to FIG. 1, there is shown an integrated MIS capacitor 10 of the prior art. In this MIS capacitor 10, two MOS transistors are made in a common semiconductor substrate. A first PMOS transistor 12 has a gate attached to one end 20 of the capacitor 10. The source and drain of the PMOS transistor 12 are electrically connected together and to the second end 30 of the MIS capacitor 10. A second NMOS transistor 14 has its gate connected to the one end 20 of the capacitor 10. The source and drain of the NMOS transistor 14 are electrically connected to the second end 30 of the MIS capacitor 10. The connection of the gates of the NMOS transistor 14 to the gate of the PMOS transistor 12 forms one end 20 of the MIS capacitor 10 while the electrical connection of the source and drain of the NMOS transistor 14 and the PMOS transistor 12 forms the second end 30 of the MIS capacitor 10. Because of the depletion region caused in the semiconductor substrate, the C-V characteristic of an M-I-S capacitor during operation is not linear. Referring to FIG. 2 there is shown a C-V graph of the operation of a prior art MIS capacitor.

Semiconductor capacitors in which one of the electrodes of the capacitor is a polysilicon layer insulated from the semiconductor substrate is also well known. In particular anti-parallel connection of semiconductor capacitors are well-known in the art. Such capacitor is exemplified by U.S. Pat. No. 4,878,151. Referring to FIG. 3, there is shown a semiconductor capacitor 110 of the prior art. A first capacitor 102a having a first electrode 104a and a second electrode 106a is connected to a first end 120 and a second end 130 respectively of the capacitor 110. A second capacitor 102b, identical to the first capacitor 102a, has its first electrode 104b connected to the second end 130 of the capacitor 110. The second electrode 106b of the second capacitor 102b is connected to the first end 120 of the capacitor 100. As a result, the first capacitor 102a and the second capacitor 102b are connected in an anti-parallel configuration. Each of the first electrodes 104a and 10b, and second electrodes 106a and 106b is manufactured from polysilicon or metal and is insulated from the semiconductor substrate. Referring to FIG. 4 there is shown a C-V graph of the operation of a prior art semiconductor capacitor, in which the C-V curve is linear. FIG. 4 is the same as FIG. 4 shown in U.S. Pat. No. 4,878,151. The connection of the first capacitor 102a and the second capacitor 102b in an anti-parallel configuration cancels the linear coefficient of the component capacitors.

Referring to FIG. 5a there is shown an NL MIS capacitor 160 of the prior art. In the NL capacitor 160, a MIS capacitor is formed by either having an N+ or a P+ gate 150 separated from the channel region 166, which has a source/drain region 162 adjacent therein. The channel region 166 is typically of one type of conductivity, albeit lightly doped, such as N−, while the source/drain region 162 is a relatively heavier doped region of that same one type of conductivity, such as N+. The source/drain region 162 and the channel region 166 can be formed in the substrate or in a well 170. The gate 150 can be N type or P type. Schematically, such a device is shown in FIG. 5b

MIS capacitors 10 have the advantage that a thinner layer of oxide (or other insulator) can be grown on the semiconductor substrate than on a layer of polysilicon. A thinner layer of oxide or other insulator results in a greater capacitance. However, MIS capacitors have the disadvantage in that they have a highly non-linear voltage variation over the full range of operation, as can be seen in FIG. 2. Although the MIS capacitor exhibits linear operation at high and low voltages, the MIS capacitor is highly non-linear in the transition region. In contrast a semiconductor capacitor using a polysilicon electrode insulated from the substrate has a linear relationship between the voltage and capacitance, as can be seen in FIG. 4.

Other prior art disclosing junction capacitors and/or capacitors with low voltage coefficient are disclosed in U.S. Pat. Nos. 5,750,426 and 5,801,411.

Heretofore, the capacitors of the prior art have been unable to provide for high capacitive density, low process complexity, and ambipolar operation (i.e. either the positive or the negative voltage with respect to the two nodes can be applied), low voltage and temperature coefficient, low external parasitic resistance and capacitance, and good matching characteristics. With respect to the prior art MIS capacitors using MOS transistors, such as that shown in FIG. 1, such capacitors have provided large variations with voltage and have been generally not been ambipolar with some parasitics. Further, they have required an extra masking step. Finally, with respect to the capacitor of the prior art, shown in FIG. 3, the shortcomings have been process complexity and/or very low density with poor matching.

Therefore, it is desirable to have a capacitor for use in analog designs that can be integrated with existing semiconductor processes which have high capacitance densities, low process complexity, ambipolar operation, low voltage and temperature coefficient over a large range, low external parasitic resistance and capacitance and good matching characteristics.

### SUMMARY OF THE INVENTION

Accordingly, in the present invention, an integrated MIS capacitor comprises a first capacitor having a first region of a first conductivity type, adjacent to a channel region of the first conductivity in a semiconductor substrate. A gate electrode is insulated and spaced apart from the channel region of the first capacitor. A second capacitor also comprises a first region of the first conductivity type. The first region is adjacent to a channel region of the first conductivity in the semiconductor substrate. A gate electrode is insulated and spaced apart from the channel region of the second capacitor. The gate electrode of the first capacitor is electrically connected to the first region of the second capacitor. The gate electrode of the second capacitor is electrically connected to the first region of the first capacitor. The integrated MIS capacitor has two terminals with one terminal being the gate electrode of the first capacitor and the second terminal being the gate electrode of the second capacitor.

### BRIEF DESCRIPTION OF THE DRAWINGS

FIG. 1 is a schematic diagram of an integrated MIS capacitor of the prior art.

FIG. 2 is a graph of C-V of the capacitor of FIG. 1 in operation.

FIG. 3 is a schematic diagram of an integrated semiconductor capacitor of the prior art.

FIG. 4 is a graph of C-V of the capacitor of FIG. 3 in operation.

FIG. 5a is a cross-sectional view of a MOS transistor of the prior art which can be used as a MIS capacitor.

FIG. 5b is a schematic diagram of the MIS capacitor shown in FIG. 5a.

FIG. 6 is a schematic diagram of the integrated MIS capacitor of the present invention.

FIG. 7 is a graph of the integrated MIS capacitor of the present invention showing the relationship between the capacitance of the capacitor and the voltage applied thereto.

FIG. 8 is a graph of capacitance versus voltage of the integrated MIS capacitor of the present invention showing the ability to tune the relationship between capacitance and voltage.

FIG. 9 a cross-sectional view of a MOS transistor used as a MIS capacitor of the present invention in which a minority contact is added.

### DETAILED DESCRIPTION OF THE PREFERRED EMBODIMENT

Referring to FIG. 6 there is shown a schematic diagram of the integrated MIS capacitor 200 of the present invention. As used herein, the term “MIS” capacitor means a capacitor in which one of the electrodes is the semiconductor substrate (or the well in a substrate) and the other electrode is a metal/polysilicon/metal silicide or any other conductive layer, insulated from the semiconductor substrate (or well). The capacitor 200 has two substantially identical MOS transistors 168 connected in an anti-parallel configuration. Each of the MOS transistors 168 has a gate 150 and a common substrate 170 wherein the source and drain of the MOS transistor 168 are electrically connected together. Alternatively, the MOS transistor 168 can comprise simply the gate 150 which is positioned above the channel region 166 in the semiconductor substrate 170, and a single region 162 which is adjacent to and surrounds the channel region 166. Thus, the gate 150a of the first MOS transistor 168a is connected to the second end 190 of the MIS capacitor 200, and the connection 170a (source and drain 162/164 connected together, or a single region 162) of the first capacitor 168a is connected to the first end 180 of the MIS capacitor 200. The gate 150b of the second MIS capacitor 168b is connected to the first end 180 of the MIS capacitor 200. The connection 170b of the second MIS capacitor 168b is connected to the second end 190 of the MIS capacitor 200.

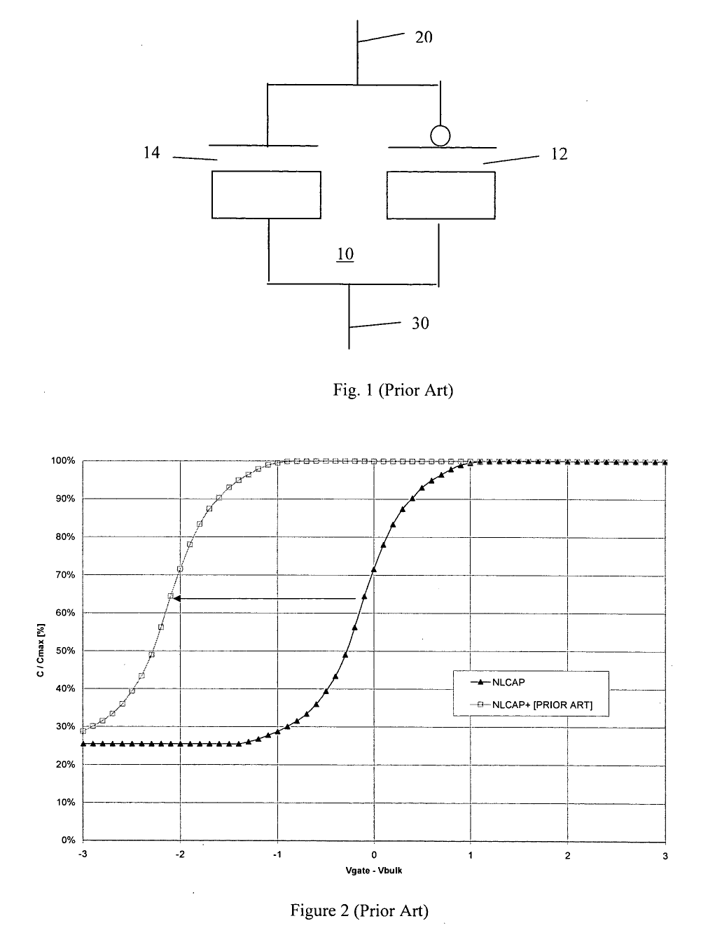

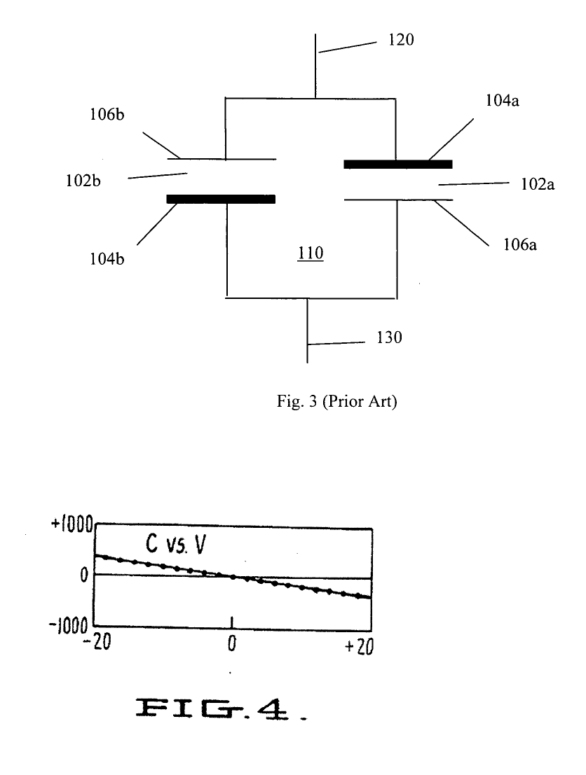

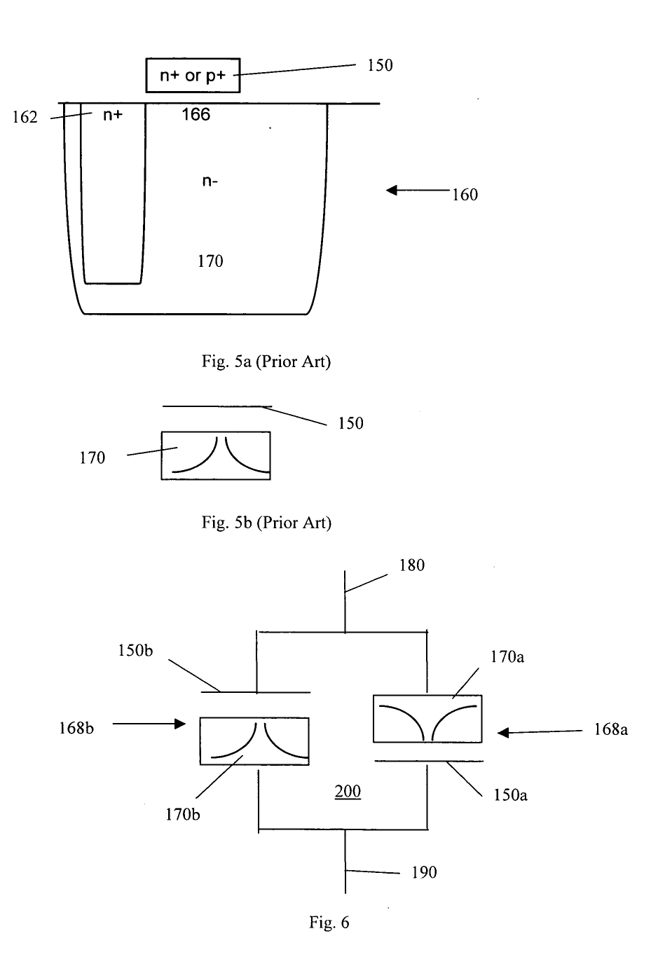

Each of the MIS capacitors 168 is of the type shown and described in FIG. 5a with a polysilicon gate 150 separated and insolated from a substrate 170. The channel region 166 and the source/drain regions 162 are of the same type of conductivity, although the semiconductor substrate (or well) 170 in which the channel region 166 and the source/drain regions 162 are formed may be of the opposite conductivity type. The source and drain 162 and 164 are connected together. Of course, as previously discussed, the substrate 170 can also be a well 170. Finally, the gate 150 can be either N-type or P-type. Both of the MIS capacitors 168a and 168b are formed in the same substrate or well 170. Thus, the MIS capacitor 200 is an integrated MIS capacitor. Further, because both of the MIS capacitors 168 are of the same type, i.e. P type or N type, unlike the integrated MIS capacitor 10 shown in FIG. 1, the MIS capacitor 200 of the present invention does not require an extra masking step. Finally, unlike the capacitor 110 of the prior art shown in FIG. 3, the present integrated MIS capacitor 200 can be processed by processes similar to those for making the rest of the electrical circuits to function with the integrated MIS capacitor 200.

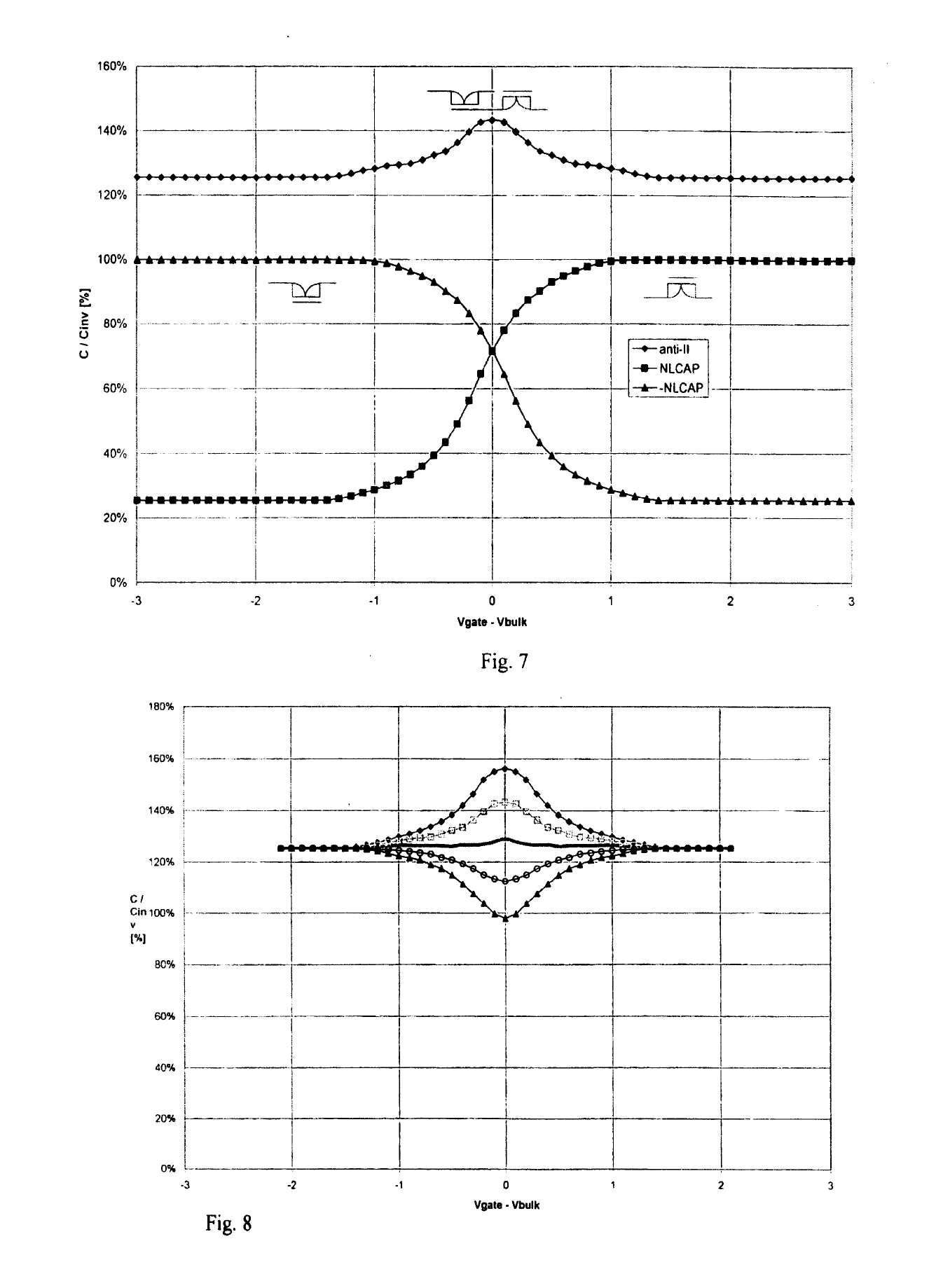

Referring to FIG. 7 there is shown a graph of the performance of the capacitor 200 of the present invention of the voltage applied as a function of the capacitance.

In the preferred embodiment, unlike the NL cap transistor of the prior art shown in FIG. 5a, which requires a high dosage implant, i.e. in excess of 10¹⁹/cm², by connecting the MIS capacitors in an anti-parallel configuration, one of the MIS capacitors 168 is always operating in an accumulation mode. Even near zero volt, the voltage variation is reduced. Furthermore, it is possible to reduce the “bump” shown in FIG. 7 near the zero volt for a lower voltage coefficient over the full range by adjusting the CMOS implant into either the channel region 166 between the source drain 162 and 164 respectively, or by adjusting the CMOS implant into the gate 150. By changing the type of species, i.e. either P or N, to dope the polysilicon gate 150, the work function of the polysilicon gate 150 can be changed. Further, by changing the doping strength of the impurity to the polysilicon gate 150, the work function of the capacitor 168 can be changed. The work function of the gate 150 also varies depending on the elemental or alloy composition of the gate material (e.g. metal, polysilicon, SiGe or the like). The ability to “tune” the MIS capacitor 200 to adjust the “bump” can be seen in FIG. 8.

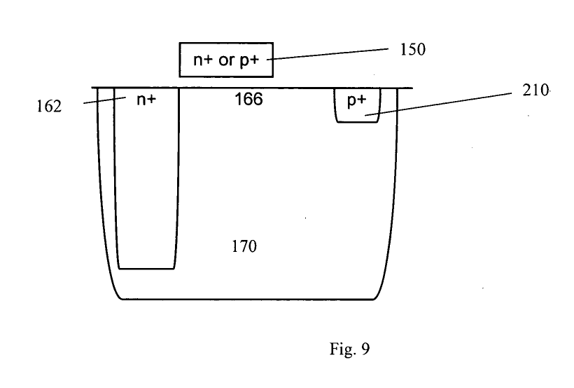

The capacitance of a MIS capacitor (or MOS transistor capacitor) for voltage>threshold (where “>” is for NMOS transistor, and “<” is for PMOS transistor) will depend on the speed of operation. At low speed the gate operates in “normal” depletion (in reality this is inversion plus depletion) mode. In contrast, at high speed operation, the capacitor operates at deep depletion. This speed-dependence is undesirable. The time constant of “high” versus “low” is determined by the strength of a minority contact. A minority contact is an optional contact 210 shown in FIG. 9 wherein a P type contact is made in an N− substrate or well 170, which may or may not be adjacent to the channel region 166. If a minority contact 210 is present, the MIS capacitor will operate at virtually “low speed” operation at all time constants of interest, which is desirable. The minority contact 210 is not connected to an electrode of the capacitor. It may, however, be connected to an electrode separate from the electrodes of the capacitor. If there is no minority contact 210, then the MIS capacitor will have an undesirable time dependence. It will operate in a high speed condition (“deep-depletion”) for most (e.g. short) times of interest. Circuit operation must be such that it accounts of this difference, by for example, resetting the capacitor, the circuit will stay within the “short” time region. The “resetting of the capacitor” may occur by biasing the capacitors 168 strongly below the Vt, or threshold voltage, in the case of a NMOS transistor. This can be accomplished by periodically applying a bias voltage between the gate 150 and the electrode 162, such that the NMOS transistor 168 is biased strongly below the Vt of the NMOS transistor. The time period for resetting the capacitor 200 is determined by the minority carrier generation lifetime, or the time constant for the formation of the inversion layer. Thus, periodically applying a bias voltage to the gate 150 and the electrode 162 such that the periodicity is less than the time constant of the formation of the inversion layer, would insure that the capacitor 200 would operate in the depletion region, which avoids a speed dependence phenomenon as discussed above.

What is claimed is:

1. An integrated metal-insulator-semiconductor (MIS) capacitor comprising:
a first capacitor comprising a first region of a first conductivity type, a channel region of the first conductivity, adjacent to the first region, in a semiconductor substrate; a gate electrode insulated and spaced apart from said channel region of said first capacitor;
a second capacitor comprising a second region of the first conductivity type, a channel region of the first conductivity adjacent to the second region, in the semiconductor substrate; a gate electrode insulated and spaced apart from said channel region of said second capacitor;
wherein said gate electrode of said first capacitor is electrically connected to the second region of said second capacitor; and
wherein said gate electrode of said second capacitor is electrically connected to the first region of said first capacitor;
wherein said MIS capacitor has two terminals: gate electrode of said first capacitor and gate electrode of said second capacitor.

2. The MIS capacitor of claim 1 wherein each of said gate electrode of said first and second capacitor is made of polysilicon of said first conductivity type.

3. The MIS capacitor of claim 1 wherein each of said gate electrode of said first and second capacitor is made of polysilicon of said second conductivity type.

4. The MIS capacitor of claim 1 wherein said substrate is a well.

5. The MIS capacitor of claim 1 wherein said first capacitor further comprising a third region of the first conductivity type spaced apart from the first region by said channel region and electrically connected to the first region.

6. The MIS capacitor of claim 5 wherein said second capacitor further comprising a fourth region of the first conductivity type spaced apart from the second region by said channel region and electrically connected to the second region.

7. The MIS capacitor of claim 1 wherein said first capacitor further comprising a contact of a second conductivity type to said semiconductor substrate.

8. The MIS capacitor of claim 7 wherein said second capacitor further comprising a contact of a second conductivity type to said semiconductor substrate.

9. A method of forming an integrated MIS capacitor having low voltage coefficient over a wide range comprising:
connecting a first capacitor to a second capacitor, each of said first and second capacitor having a first region of a first conductivity type, adjacent to a channel region of the first conductivity type, in a semiconductor substrate, with a gate electrode insulated and spaced apart from the channel region, wherein the gate of the first capacitor is electrically connected to the first region of the second capacitor, and the gate of the second capacitor is electrically connected to the first region of the first capacitor; and
adjusting the voltage coefficient of the first and second capacitor.

10. The method of claim 9 wherein said voltage coefficient is adjusted by doping the gates of the first and second capacitor by the first conductivity type.

11. The method of claim 9 wherein said voltage coefficient is adjusted by doping the gates of the first and second capacitor by the second conductivity type.

12. The method of claim 9 wherein said voltage coefficient is adjusted by selecting an alloy or elemental composition for said gate with the desired work function.

13. A method of forming an integrated MIS capacitor having low voltage coefficient over a wide range comprising:
connecting a first capacitor to a second capacitor, each of said first and second capacitor having a first region of a first conductivity type, adjacent to a channel region of the first conductivity type, in a semiconductor substrate, with a gate electrode insulated and spaced apart from the channel region, wherein the gate of the first capacitor is electrically connected to the first region of the second capacitor, and the gate of the second capacitor is electrically connected to the first region of the first capacitor; and
adjusting the voltage coefficient by doping the channel regions of the first and second capacitor.

14. A method of operating an integrated metal-insulator-semiconductor (MIS) capacitor of the type having a first capacitor and a second capacitor, wherein each of said first and second capacitors has a first region of a first conductivity type, adjacent to a channel region of the first conductivity type, in the same semiconductor substrate, wherein each of said channel region characterized by a threshold voltage, a gate electrode insulated and spaced apart from the channel region, wherein the gate of the first capacitor is electrically connected to the first region of the second capacitor, and the gate of the second capacitor is electrically connected to the first region of the first capacitor; wherein said method comprising:
periodically setting the gate electrode of the first capacitor to an accumulation bias, wherein the period is less than the time constant for the formation of an inversion layer in the channel of the first capacitor.

15. The method of claim 14 wherein said setting comprises applying a voltage between the gate electrode of the first capacitor and the first region of the first capacitor wherein said voltage biases said first capacitor below the threshold voltage of said channel of first capacitor.

16. The method of claim 15 further comprising:
periodically applying a voltage between the gate electrode of the second capacitor and the first region of the second capacitor wherein said voltage biases said second capacitor below the threshold voltage, wherein said voltage is applied periodically with a period less than the time constant for the formation of an inversion layer in said channel region.
